(19) United States
(12) Patent Application Publication
(10) Pub. No.: US 2026/0052987 A1
(43) Pub. Date: Feb. 19, 2026

(54) SEMICONDUCTOR PACKAGES AND SEMICONDUCTOR DEVICES COMPRISING HEAT TRANSFER MEMBER

(71) Applicant: Samsung Electronics Co., Ltd., Suwon-si (KR)

(72) Inventor: Kwang Woong Ahn, Suwon-si (KR)

(21) Appl. No.: 19/049,327

(22) Filed: Feb. 10, 2025

(30) Foreign Application Priority Data
Aug. 14, 2024 (KR) 10-2024-0109001

(51) Int. Cl. H01L 23/373; H01L 23/00; H01L 23/498; H01L 23/538; H01L 25/16; H10F 39/00; H10F 39/95

(52) U.S. Cl. CPC H01L 23/3735; H01L 23/49816; H01L 23/5385; H01L 24/32; H01L 25/167; H10F 39/804; H10F 39/95; H01L 24/16; H01L 24/48; H01L 24/73; H01L 2224/16227; H01L 2224/32225; H01L 2224/48227; H01L 2224/73253; H10F 39/811

(57) ABSTRACT

Provided is a semiconductor package that may improve heat dissipation performance, including a package substrate on a system substrate, in which the package substrate includes a first surface and a second surface opposite the first surface, the second surface facing the system substrate, a connection member electrically connecting the system substrate and the package substrate, a first semiconductor chip on the first surface of the package substrate, a second semiconductor chip on the second surface of the package substrate, and electrically connected to the first semiconductor chip, and a heat transfer member between the second semiconductor chip and the system substrate.

### CROSS-REFERENCE TO RELATED APPLICATION

This application claims priority to Korean Patent Application No. 10-2024-0109001, filed in the Korean Intellectual Property Office on Aug. 14, 2024, the entire contents of which are hereby incorporated by reference.

### FIELD

The present disclosure relates to a semiconductor package and a semiconductor device.

### BACKGROUND OF THE INVENTION

Semiconductor devices generate heat during power consumption and operation. If the heat generated in the semiconductor device is not properly dissipated, the temperature of the semiconductor device may rise, causing various problems. For example, at high temperatures, the electrical characteristics of the semiconductor device may change, causing performance degradation, malfunction, or even permanent damage in severe cases. Therefore, the heat dissipation performance of the semiconductor device may be important for maintaining the performance and reliability of the semiconductor device.

Heat management may be particularly important in semiconductor devices that include an image sensor. The image sensor is a component that converts light into electrical signals and is highly sensitive to heat. If the heat is transferred to the image sensor, the performance of the image sensor may degrade, and distortion may occur in the images.

The information described above is intended to improve understanding of the background of the present disclosure, and may include information that does not constitute the related art.

### SUMMARY OF THE INVENTION

In order to solve one or more problems (e.g., the problems described above and/or other problems not explicitly described herein), the present disclosure provides a semiconductor package and a semiconductor device.

The problems to be solved by the present disclosure are not limited to those described above, and other problems not mentioned can be clearly understood by those skilled in the art from the description of the disclosure below.

According to some embodiments, a semiconductor package may include a package substrate on a system substrate, in which the package substrate may include a first surface and a second surface opposite the first surface, the second surface facing the system substrate, a connection member electrically connecting the system substrate and the package substrate, a first semiconductor chip on the first surface of the package substrate, a second semiconductor chip on the second surface of the package substrate, and electrically connected to the first semiconductor chip, and a heat transfer member between the second semiconductor chip and the system substrate.

According to some embodiments, a semiconductor device may include a system substrate and a semiconductor package on the system substrate, in which the semiconductor package may include a package substrate including a first surface and a second surface opposite the first surface, the second surface facing the system substrate, a connection member electrically connecting the system substrate and the package substrate, a first semiconductor chip on the first surface of the package substrate, a second semiconductor chip on the second surface of the package substrate, and electrically connected to the first semiconductor chip, and a heat transfer member between the second semiconductor chip and the system substrate.

According to some embodiments, a semiconductor device may include a system substrate and an image sensor package on the system substrate, in which the image sensor package may include a package substrate including a first surface and a second surface opposite the first surface and facing the system substrate,, and a wiring pattern formed between the first surface and the second surface, a connection member electrically connecting the system substrate and the package substrate, an image sensor chip on the first surface of the package substrate, and including a pixel area at a central region of an upper surface of the image sensor chip, and a peripheral area surrounding the pixel area, a dam in a shape of a ring surrounding the pixel area on the peripheral area of the image sensor chip, a transparent cover member on the dam and on an upper portion of the image sensor chip, a molding member on outer surfaces of the image sensor chip, the dam, and the transparent cover, an image signal processor chip on the second surface of the package substrate and electrically connected to the image sensor chip through the wiring pattern of the package substrate; and a heat transfer member between the image signal processor chip and the system substrate, in which a first portion of the heat transfer member may be in contact with the image signal processor chip and a second portion may be in contact with the system substrate.

The effects that can be obtained through the present disclosure are not limited to those described above. Technical effects not mentioned herein will be clearly understood by those skilled in the art from the description of the present disclosure described below.

### BRIEF DESCRIPTION OF THE DRAWINGS

The above and other objects, features and advantages of the present disclosure will become more apparent to those of ordinary skill in the art by describing in detail example embodiments thereof with reference to the accompanying drawings, in which:

FIGS. 1, 2, and 3 are a cross-sectional view, plan view, and bottom view illustrating an example of a semiconductor package, respectively;

FIGS. 4 and 5 are a cross-sectional view and plan view illustrating an example of a semiconductor package, respectively;

FIG. 6 is a cross-sectional view illustrating an example of a semiconductor device;

FIG. 7 is a plan view illustrating an example of a system substrate included in the semiconductor device of FIG. 6;

FIG. 8 is a cross-sectional view illustrating an example of a semiconductor device;

FIG. 9 is a plan view illustrating an example of a system substrate included in the semiconductor device of FIG. 8;

FIG. 10 is a diagram illustrating an example of heat dissipation paths in a semiconductor device according to a comparative example and in a semiconductor device according to embodiments of the present disclosure; and

FIG. 11 to 16 are schematic cross-sectional views illustrating an example of a method for manufacturing a semiconductor device.

### DETAILED DESCRIPTION

According to various aspects of the present disclosure, the heat transfer member may transfer heat generated by the semiconductor chip to the system substrate side and may have excellent heat dissipation performance. As a result, the heat generated in the semiconductor device may be smoothly or more uniformly discharged, and the amount of heat transferred to the other semiconductor chips disposed on the package substrate and/or the package substrate itself may be reduced. With this configuration, the heat dissipation characteristics of the semiconductor device may be improved, and the performance and reliability of the semiconductor device may be enhanced.

According to various aspects of the present disclosure, the heat transfer member may support the semiconductor chip between the semiconductor chip and the system substrate. As a result, the mechanical strength of the semiconductor device may be reinforced, and a warpage phenomenon, where the semiconductor device bends or deforms, may be reduced or prevented. As a result, the performance and reliability of the semiconductor device may be enhanced.

According to various aspects of the present disclosure, the heat-receiving pad may receive the heat transferred from the heat transfer member, so that the heat may be smoothly or more uniformly conveyed to the system substrate side. As a result, the heat generated in the semiconductor device may be smoothly or more uniformly discharged, and the amount of heat transferred to the other semiconductor chips disposed on the package substrate and/or the package substrate itself may be more effectively reduced. With this configuration, the heat dissipation characteristics of the semiconductor device may be greatly improved, and the performance and reliability of the semiconductor device may be enhanced.

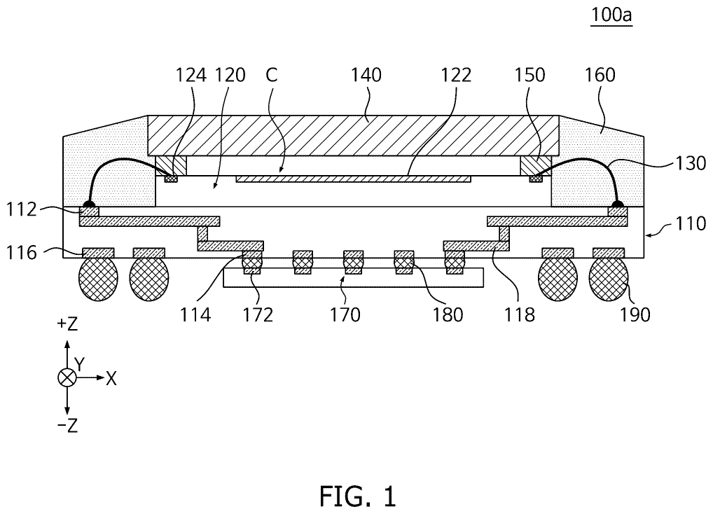

Various aspects of the present disclosure will be described with reference to FIGS. 1 to 16. Throughout the description, the same reference numerals may refer to the same components, and redundant descriptions thereof may be omitted.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

Components or layers described with reference to “overlap” in a particular direction may be at least partially obstructed by one another when viewed along a line extending in the particular direction or in a plane perpendicular to the particular direction. The term “surrounding” or “covering” or “filling” or “enclosing” as may be used herein may not require completely surrounding or covering or filling the described elements or layers, but may, for example, refer to partially surrounding or covering or filling or enclosing the described elements or layers, for example, with voids or other spaces throughout.

It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

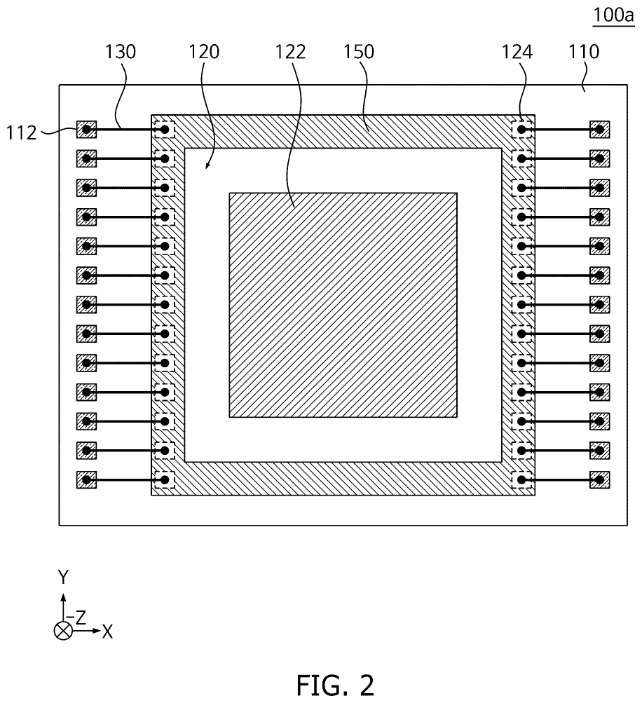

FIGS. 1, 2, and 3 are cross-sectional view, plan view, and bottom view illustrating an example of a semiconductor package 100a, respectively. In the present disclosure, a plan view may refer to an illustration of an object viewed from a +Z direction (e.g., from above), and a bottom view may refer to an illustration of the object viewed from a-Z direction (e.g., from below). For convenience of explanation, certain configurations (e.g., a transparent cover member 140, a molding member 160) are omitted from the plan view of FIG. 2. In addition, for convenience of explanation, certain configurations (e.g., a first chip pad 124) that are obscured from the view by the other configurations when viewed from the +Z direction are illustrated in the plan view of FIG. 2.

The semiconductor package 100a may include a package substrate 110, a first semiconductor chip 120, a bonding wire 130, a second semiconductor chip 170, and a bump 180.

The package substrate 110 may be a printed circuit board (PCB). In some embodiments, the package substrate 110 may be a multilayer printed circuit board including a substrate base including a plurality of stacked base layers. In some embodiments, each of the plurality of base layers of the substrate base may be formed of at least one material selected from among phenol resin, epoxy resin, or polyimide. For example, each of the plurality of base layers of the substrate base may include at least one material selected from among Flame Retardant 4 (FR4), tetrafunctional epoxy, polyphenylene ether, epoxy/polyphenylene oxide, bismaleimidetriazine (BT), thermount, cyanate ester, polyimide, or liquid crystal polymer.

The package substrate 110 may have a first surface (e.g., an upper surface) and a second surface (e.g., a lower surface) opposite the first surface. The package substrate 110 may include pads 112, 114, and 116 formed on the first surface and/or the second surface. For example, the package substrate 110 may include one or more the bonding pads 112 on the first surface and one or more contact pads 114 and 116 on the second surface.

The package substrate 110 may include a wiring layer 118 formed between the first surface and the second surface. The wiring layer 118 may include a wiring pattern and a wiring via. The wiring pattern may be disposed on an upper surface and/or a lower surface of each of the plurality of base layers. For example, the wiring pattern may include an electrolytically deposited (ED) copper foil, a rolled-annealed (RA) copper foil, a stainless steel foil, an aluminum foil, ultra-thin copper foils, sputtered copper, copper alloys, etc. The wiring via may electrically connect between the wiring patterns. The wiring via may be formed through at least one of the plurality of base layers. In some embodiments, the wiring via may be formed of copper, nickel, stainless steel, beryllium copper, etc. The wiring layer 118 may electrically connect at least some of the pads 112, 114, and 116 formed on the package substrate 110.

The first semiconductor chip 120 and the second semiconductor chip 170 may each include a semiconductor substrate and a wiring layer. The semiconductor substrate may be formed of, for example, a silicon bulk wafer or an epitaxial wafer. The epitaxial wafer may include a crystalline material layer grown on a bulk substrate by an epitaxial process, that is, an epitaxial layer. Without being limited to the bulk wafer or the epitaxial wafer, the semiconductor substrate may be formed using various wafers such as polished wafers, annealed wafers, silicon on insulator (SOI) wafers, etc. The wiring layer may be formed on at least one surface of the semiconductor substrate. For example, the wiring layer may be formed on an active surface of the semiconductor substrate (e.g., a surface where the semiconductor elements are formed).

The first semiconductor chip 120 may be disposed on the first surface of the package substrate 110. The first semiconductor chip 120 may be disposed on the package substrate 110 such that an inactive surface thereof faces the first surface of the package substrate 110. An inactive surface of a semiconductor chip may be a surface that is opposite to a surface adjacent active electronic components or otherwise does not participate in active electronic functions, such as a passivated surface. A separate adhesive member (e.g., die attach film (DAF)) may be interposed between the first surface of the package substrate 110 and the first semiconductor chip 120.

The first semiconductor chip 120 may be mounted on the package substrate 110 by a wire bonding method. For example, the first chip pad 124 may be formed on the active surface of the first semiconductor chip 120. As a specific example, as illustrated in FIG. 2, the first chip pad 124 may be formed along both side edges of an upper surface of the first semiconductor chip 120 in a first direction (e.g., Y direction), but embodiments are not limited thereto. The first chip pad 124 may be electrically connected to the wiring layer of the first semiconductor chip 120. In addition, the bonding pads 112 may be formed around the first chip pad 124 on the first surface of the package substrate 110. The bonding wire 130 may electrically connect the first chip pad 124 and the bonding pad 112. The first semiconductor chip 120 and the package substrate 110 may be electrically connected to each other through the bonding wire 130. The bonding wire 130 may include a metal such as gold (Au), copper (Cu), silver (Ag), aluminum (Al), etc.

The second semiconductor chip 170 may be disposed on the second surface of the package substrate 110. The second semiconductor chip 170 may be disposed on the package substrate 110 such that an active surface thereof faces the second surface of the package substrate 110. An active surface may be a surface that is adjacent active electronic components or otherwise includes components that provide active electronic functions.

The second semiconductor chip 170 may be mounted on the package substrate 110 by a flip-chip method. For example, a second chip pad 172 may be formed on the active surface of the second semiconductor chip 170. As a specific example, the second chip pad 172 may be disposed in a two-dimensional array structure on the active surface of the second semiconductor chip 170, but embodiments are not limited thereto. The second chip pad 172 may be electrically connected to the wiring layer of the second semiconductor chip 170. In addition, a first contact pad 114 may be formed on the second surface of the package substrate 110 to correspond to the arrangement structure of the second chip pad 172. The bump 180 may be interposed between the second semiconductor chip 170 and the package substrate 110 to electrically connect the second chip pad 172 and the first contact pad 114. The second semiconductor chip 170 and the package substrate 110 may be electrically connected to each other through the bump 180.

The second semiconductor chip 170 may be electrically connected to the first semiconductor chip 120 through the package substrate 110 to transmit and receive signals and/or power. For example, the first semiconductor chip 120 and the second semiconductor chip 170 may be electrically connected to each other through the bonding wire 130, the package substrate 110 (e.g., the bonding pad 112, the wiring layer 118, and the first contact pad 114 included in the package substrate 110), and the bump 180 to transmit and receive signals and/or power.

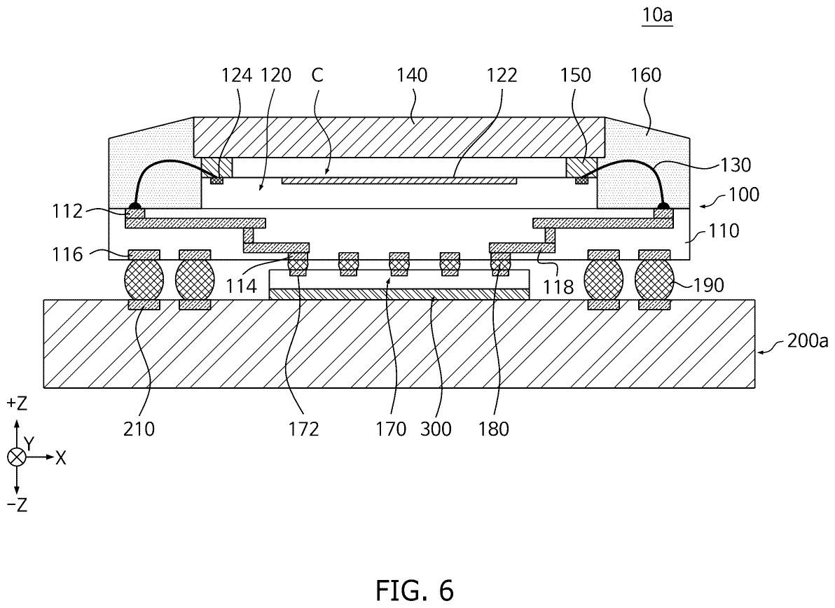

The semiconductor package 100a may include a heat transfer member 300 (see FIG. 6). For example, the heat transfer member 300 (see FIG. 6) may be disposed on the inactive surface of the second semiconductor chip 170. The inactive surface of the second semiconductor chip 170 may be a surface opposite to the active surface. The heat transfer member may be interposed between the second semiconductor chip 170 and a system substrate 200a (see FIG. 6). The heat transfer member may contact the second semiconductor chip 170 and the system substrate to transfer heat generated by the second semiconductor chip to the system substrate. The heat transfer member will be described in more detail below with reference to FIG. 6.

The semiconductor package 100a may further include the molding member 160. The molding member 160 may be positioned on the first surface of the package substrate 110. The molding member 160 may cover at least a portion of outer surfaces of the components disposed on the first surface of the package substrate 110. For example, the molding member 160 may cover at least a portion of a side surface of the first semiconductor chip 120 and at least a portion of the bonding wire 130. The molding member 160 may include epoxy molding compound (EMC). However, embodiments are not limited thereto, and the molding member 160 may include various materials such as epoxy-based materials, thermosetting materials, thermoplastic materials, UV-treated materials, etc.

Although not illustrated, the semiconductor package 100a may further include an underfill layer covering the bump 180. For example, the underfill layer may include an underfill resin such as epoxy resin, silica filler, or flux, but not limited thereto.

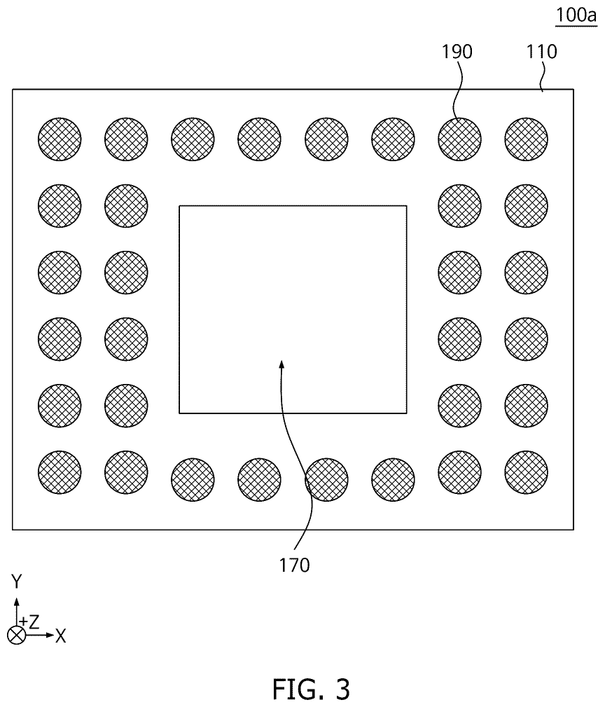

The semiconductor package 100a may further include a connection member 190. For example, a second contact pad 116 may be formed on the second surface of the package substrate 110. As a specific example, the second contact pad 116 may be formed on the second surface of the package substrate 110, surrounding the area where the first contact pad 114 is formed. The connection member 190 may be attached onto the second contact pad 116 formed on the second surface of the package substrate 110. That is, as illustrated in FIG. 3, the connection member 190 may be disposed to surround the second semiconductor chip 170 and the first contact pad 114. For example, the connection member 190 may be formed as a solder ball. The package substrate 110 may be connected to an external component (e.g., a system substrate, etc.) through the connection member 190.

The first semiconductor chip 120 may be an image sensor chip. In this case, the first semiconductor chip 120 may include a sensor unit 122 positioned at the center or central region of the first semiconductor chip 120. The sensor unit 122 may include a pixel area including a plurality of pixels. The pixel area may be referred to as an active pixel sensor (APS) area. In the pixel area, the pixels may be disposed in a 2D array structure. Each of the pixels in the pixel area may include a photo-diode (PD) formed in the semiconductor substrate. The photo-diode may be formed through an ion implantation process that injects impurity ions into the pixel area. Each of the pixels in the pixel area may absorb incident light, generate and accumulate charges corresponding to the amount of light, and transmit the accumulated charges to the outside as an electrical signal through a pixel transistor. That is, if the first semiconductor chip 120 is the image sensor chip, the first semiconductor chip 120 may convert the incoming light signal into an electrical signal (analog signal). The pixel transistor may include, for example, a transfer transistor, a source follower transistor, a reset transistor, and a selection transistor, etc. A color filter and a microlens may be disposed on an upper portion of the pixel area. In some embodiments in which the first semiconductor chip 120 is the image sensor chip, the first chip pad 124 may be formed on a peripheral area of an upper surface of the first semiconductor chip 120, which is an area surrounding the sensor unit 122.

In some embodiments in which the first semiconductor chip 120 is the image sensor chip, the semiconductor package 100a may further include a dam 150 and the transparent cover member 140.

The dam 150 may be disposed in the peripheral area of the upper surface of the first semiconductor chip 120, which is an area surrounding the sensor unit 122 (e.g., the pixel area). The dam 150 may be in the form of a ring surrounding the sensor unit 122. For example, the dam 150 may have a shape of a rectangular ring surrounding the sensor unit 122 of the first semiconductor chip 120 with a predetermined height.

As illustrated in FIGS. 1 and 2, the dam 150 may cover at least a portion of the first chip pad 124. In this case, the dam 150 may also cover one end of the bonding wire 130 connected to the first chip pad 124.

The dam 150 may include epoxy resin and/or silicone-based material, etc., but not limited to these. Meanwhile, the epoxy resin, which may be cured by UV light and serve as an adhesive, may also be referred to as UV glue, UV epoxy glue, etc.

The transparent cover member 140 may be disposed on the dam 150 and may cover an upper portion of the first semiconductor chip 120. For example, the transparent cover member 140 may be spaced apart from the upper surface of the first semiconductor chip 120 by the height of the dam 150. That is, the transparent cover member 140 may cover the upper portion of the first semiconductor chip 120 with a gap corresponding to the height of the dam 150.

Accordingly, there may be an empty space, that is, a cavity C, between the transparent cover member 140 and the first semiconductor chip 120. That is, the cavity C may be formed in a space defined between the transparent cover member 140 and the first semiconductor chip 120 and at a center or central region surrounded by the dam 150. The transparent cover member 140 may include, for example, transparent glass, transparent resin, light-transmitting ceramics, etc., but is not limited thereto.

The dam 150 may support the transparent cover member 140 on the first semiconductor chip 120, seal the cavity C, and prevent moisture or foreign substances from entering the cavity C from the outside. That is, the dam 150 may prevent the first semiconductor chip 120, especially the sensor unit 122, from being contaminated by the moisture or foreign substances.

In some embodiments in which the semiconductor package 100a includes the dam 150 and the transparent cover member 140, the molding member 160 may cover the outer surfaces of the first semiconductor chip 120, the dam 150, and the transparent cover member 140. For example, the molding member 160 may be disposed on the first surface of the package substrate 110 and may seal the first semiconductor chip 120, the bonding wire 130, and the transparent cover member 140. Specifically, the molding member 160 may be formed to cover the first surface of the package substrate 110, and the side surfaces of the first semiconductor chip 120 and the transparent cover member 140. In addition, the molding member 160 may cover the outer surfaces of the bonding wire 130 and the dam 150. The molding member 160, in conjunction with the dam 150, may prevent the sensor unit 122 of the first semiconductor chip 120 from being contaminated by foreign substances. In addition, the molding member 160 may protect the semiconductor package 100a from external impact.

As illustrated in FIG. 1, the upper surface of the molding member 160 may be slightly sloped with respect to an upper surface of the transparent cover member 140. However, embodiments are not limited thereto, and according to other embodiments, the upper surface of the molding member 160 may be formed substantially on the same plane as (i.e. may be coplanar with) the upper surface of the transparent cover member 140.

In some embodiments in which the first semiconductor chip 120 is the image sensor chip, the second semiconductor chip 170 may include a semiconductor chip electrically connected to the image sensor chip to exchange signals and/or power with the image sensor chip. The second semiconductor chip 170 may include an image signal processor (ISP) that converts the electrical signal (e.g., analog signal) generated by the image sensor chip into a digital signal. Additionally or alternatively, the second semiconductor chip 170 may include a power management integrated circuit (PMIC) that manages the power provided to the image sensor chip. In some embodiments in which the first semiconductor chip 120 is the image sensor chip, the semiconductor package 100a may also be referred to as an image sensor package.

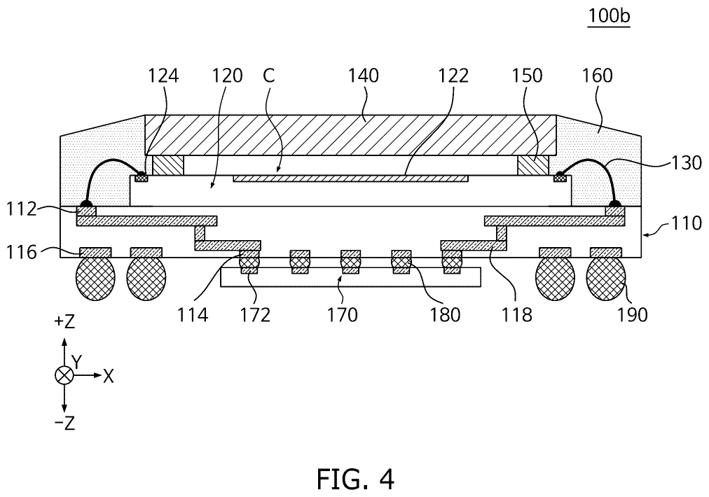

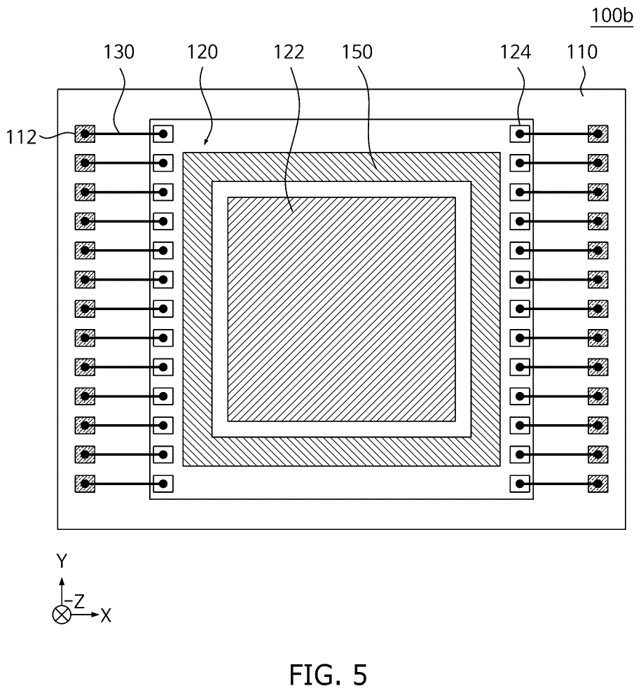

FIGS. 4 and 5 illustrate a cross-sectional view and a plan view illustrating an example of a semiconductor package 100b, respectively. For convenience of explanation, certain components (e.g., the transparent cover member 140, the molding member 160) are omitted from the plan view of FIG. 5. Most of the description provided above with reference to FIGS. 1 to 3 may be applicable in the same or similar manner to the semiconductor package 100b of FIGS. 4 and 5. Hereinbelow, the elements or operations already described above with reference FIGS. 1 to 3 will not be described, and the description will focus on additions/changes.

Referring to FIGS. 4 and 5, in the semiconductor package 100b, the dam 150 may be disposed in an area of the upper surface of the first semiconductor chip 120 where the first chip pad 124 is not formed. For example, the dam 150 may be disposed in a peripheral area surrounding the sensor unit 122 on the upper surface of the first semiconductor chip 120, and the first chip pad 124 may be formed in the peripheral area and outside the area where the dam 150 is disposed. In this case, the dam 150 may not overlap or cover the first chip pad 124 and the bonding wire 130. In this case, the molding member 160 may cover all of the first chip pad 124 and the bonding wire 130.

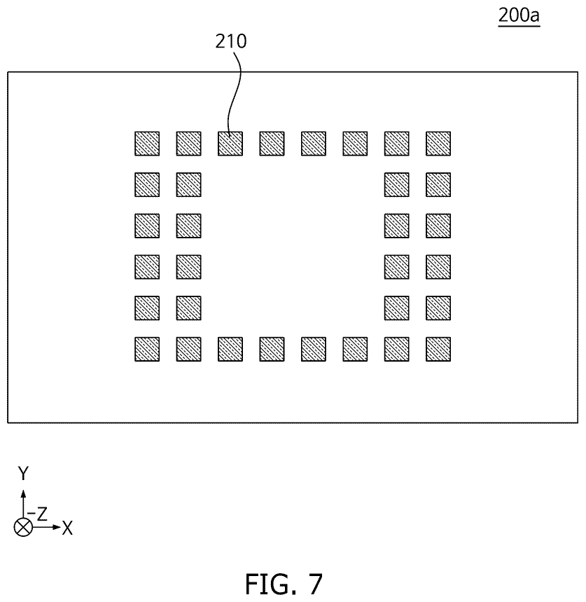

FIG. 6 illustrates a cross-sectional view illustrating an example of a semiconductor device 10a, and FIG. 7 illustrates a plan view illustrating an example of the system substrate 200a included in the semiconductor device 10a illustrated in FIG. 6. Referring to FIGS. 6 and 7, the semiconductor device 10a may include the system substrate 200a and a semiconductor package 100. Most of the description provided above with reference to FIGS. 1 to 5 may be applicable in the same or similar manner to the semiconductor package 100 included in the semiconductor device 10a of FIG. 6. Hereinbelow, the elements or operations already described above with reference FIGS. 1 to 5 will not be described, and the description will focus on additions/changes.

The system substrate 200a may be a printed circuit board (PCB). In some embodiments, the system substrate 200a may be a multilayer printed circuit board including a substrate base including a plurality of stacked base layers. The system substrate 200a may include a substrate pad 210 formed on at least one surface. For example, the system substrate 200a may include one or more substrate pads 210 on its upper surface.

Although not illustrated, the system substrate 200a may include a wiring layer. The wiring layer may include a wiring pattern and a wiring via. The wiring pattern may be disposed on upper and/or lower surfaces of each of the plurality of base layers. The wiring via may electrically connect between the wiring patterns. The wiring via may be formed through at least one of the plurality of base layers. The wiring layer may electrically connect at least some of the substrate pads 210 formed on the system substrate 200a.

The number of layers of the wiring pattern formed within the system substrate 200a may be greater than the number of layers of the wiring pattern formed within the package substrate 110. Since the wiring pattern may include a material with excellent thermal conductivity (e.g., a metal material), the system substrate 200a with the wiring pattern of more layers may have superior heat dissipation performance compared to the package substrate 110.

The semiconductor package 100 may be disposed on the system substrate 200a. For example, the semiconductor package 100 may be disposed on the system substrate 200a such that the second surface of the package substrate 110 (the surface on which the second semiconductor chip 170 is disposed) faces the system substrate 200a (e.g., the upper surface of the system substrate 200a).

The system substrate 200a and the semiconductor package 100 may be electrically connected through the connection member 190. For example, the substrate pad 210 may be formed on one surface (e.g., an upper surface) of the system substrate 200a. The substrate pad 210 may be formed on one surface of the system substrate 200a to correspond to the second contact pad 116 formed on the second surface of the package substrate 110. As a specific example, the second contact pad 116 may be formed on the second surface of the package substrate 110 to surround the area on the upper surface of the system substrate 200a where the second semiconductor chip 170 is positioned, as illustrated in FIG. 7. The connection member 190 may be interposed between the second contact pad 116 of the package substrate 110 and the substrate pad 210 of the system substrate 200a to electrically connect the package substrate 110 and the system substrate 200a. That is, the package substrate 110 and the system substrate 200a may be electrically connected through the connection member 190. Although it is illustrated herein that the connection member 190 is included in the semiconductor package 100, embodiments are not limited thereto. For example, according to another embodiment, the connection member 190 may be included in the system substrate 200a or included in the semiconductor device 10a as a separate component from the semiconductor package 100 and the system substrate 200a or may be formed by combining sub-connection members 190 included in each of the semiconductor package 100 and the system substrate 200a.

In addition, the semiconductor device 10a may further include the heat transfer member 300. In some embodiments, the heat transfer member 300 may be included in the semiconductor package 100, included in the system substrate 200a, or included in the semiconductor device 10a as a separate component from the semiconductor package 100 and the system substrate 200a, or may be formed by combining the sub-heat transfer members included in each of the semiconductor package 100 and the system substrate 200a. The sub-heat transfer members together may form the heat transfer member 300.

The heat transfer member 300 may be interposed between the second semiconductor chip 170 and the system substrate 200a. The heat transfer member 300 may be in contact with the semiconductor chip and the system substrate 200a. For example, a portion of the heat transfer member 300 may be in contact with the second semiconductor chip 170, and another portion may be in contact with the upper surface of the system substrate 200a.

The heat transfer member 300 may include a material with excellent thermal conductivity. Specifically, the heat transfer member 300 may include a material with better or higher thermal conductivity than air. The heat transfer member 300 may include a material with excellent thermal conductivity and adhesion. For example, the heat transfer member 300 may include an epoxy-based material (e.g., epoxy resin), but is not limited thereto.

The heat transfer member 300 may be formed of the same material as the connection member 190. For example, the connection member 190 and the heat transfer member 300 may include a metal such as tin (Sn), copper (Cu), silver (Ag), etc., or a combination of at least some of these, but not limited thereto.

The heat transfer member 300 may transfer the heat generated by the second semiconductor chip 170 toward the system substrate 200a that has superior heat dissipation performance. As a result, the heat generated in the semiconductor device 10a may be smoothly or more uniformly discharged, and the amount of heat transferred to the first semiconductor chip 120 disposed on the package substrate 110 and/or the package substrate 110 may be reduced. Thus, the heat dissipation characteristics of the semiconductor device 10a may be improved, and the performance and reliability of the semiconductor device 10a may be enhanced.

In addition, the heat transfer member 300 may support the second semiconductor chip 170 between the second semiconductor chip 170 and the system substrate 200a (i.e., from below the second semiconductor chip 170). As a result, the mechanical strength of the semiconductor device 10a may be reinforced, and the warpage phenomenon, where the semiconductor device 10a bends or deforms, can be reduced or prevented. As a result, the performance and reliability of the semiconductor device 10a may be improved.

Depending on circumstances, the semiconductor device 10a according to some embodiments may also be referred to as a semiconductor system or a semiconductor package.

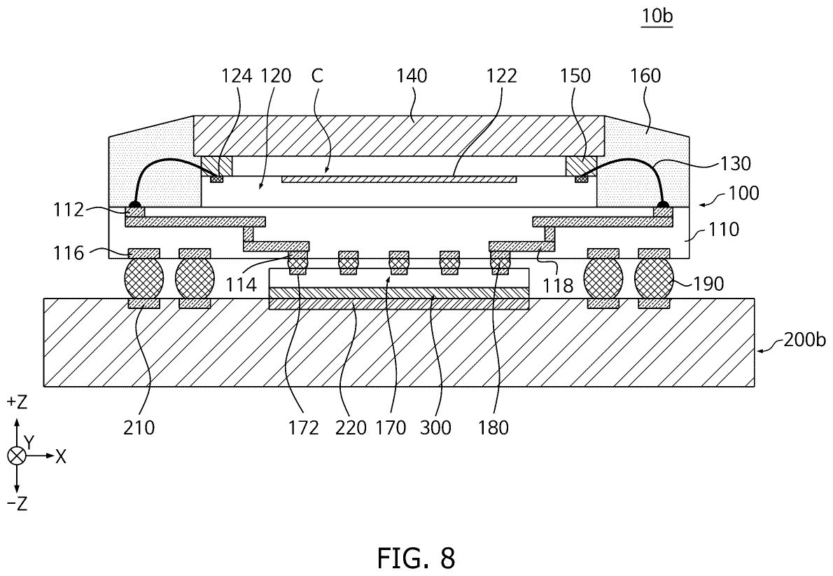

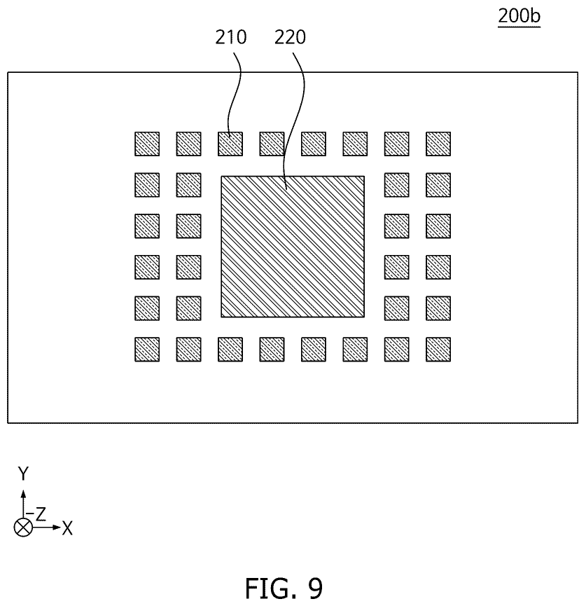

FIG. 8 is a cross-sectional view illustrating an example of a semiconductor device 10b, and FIG. 9 is a plan view illustrating an example of a system substrate 200b included in the semiconductor device 10b of FIG. 8. Most of the description provided above with reference to FIGS. 1 to 7 may be equally/similarly applicable to the description below. Hereinbelow, the elements or operations already described above with reference FIGS. 1 to 7 will not be described, and the description will focus on additions/changes.

Referring to FIGS. 8 and 9, the system substrate 200b included in the semiconductor device 10b may further include a heat-receiving pad 220. For example, the heat-receiving pad 220 may be formed on one surface (e.g., the upper surface) of the system substrate 200b. The heat-receiving pad 220 may be formed on an area on one surface (e.g., the upper surface) of the system substrate 200b, which is surrounded by the substrate pads 210.

The heat transfer member 300 may be disposed on the heat-receiving pad 220. For example, the heat transfer member 300 may be in contact with the heat-receiving pad 220 of the system substrate 200b. Specifically, a portion of the heat transfer member 300 may be in contact with the second semiconductor chip 170, and another portion may be in contact with the heat-receiving pad 220 of the system substrate 200b.

The cross-sectional area of the heat-receiving pad 220 in a horizontal direction (in a X-Y plane direction of FIGS. 8 and 9) may correspond to the cross-sectional area of the second semiconductor chip 170 in the horizontal direction. For example, the horizontal cross-sectional area of the heat-receiving pad 220 may be the same as or greater than the horizontal cross-sectional area of the second semiconductor chip 170. As a specific example, the horizontal cross-sectional area of the heat-receiving pad 220 may be at least equal to 1 times and at most 1.1 times the horizontal cross-sectional area of the second semiconductor chip 170, but embodiments are not limited thereto.

The heat-receiving pad 220 may include a material with excellent thermal conductivity. The heat-receiving pad 220 may be formed of the same or similar material as the substrate pad 210. For example, the heat-receiving pad 220 may include a metal such as Aluminum (Al), Copper (Cu), Gold (Au), Nickel (Ni), Titanium (Ti), Tungsten (W), or at least a combination thereof, but is not limited thereto. The thermal conductivity of the heat-receiving pad 220 may be better than the thermal conductivity of the heat transfer member 300, but embodiments are not limited thereto.

By the heat-receiving pad 220 that receives the heat transferred from the heat transfer member 300, the heat may be smoothly or more uniformly transferred toward the system substrate 200b. As a result, the heat generated in the semiconductor device 10b may be smoothly or more uniformly discharged, and the amount of heat transferred to the first semiconductor chip 120 disposed on the package substrate 110 and/or the package substrate 110 may be more effectively reduced. Thus, the heat dissipation characteristics of the semiconductor device 10b can be greatly improved, and the performance and reliability of the semiconductor device 10b can be enhanced.

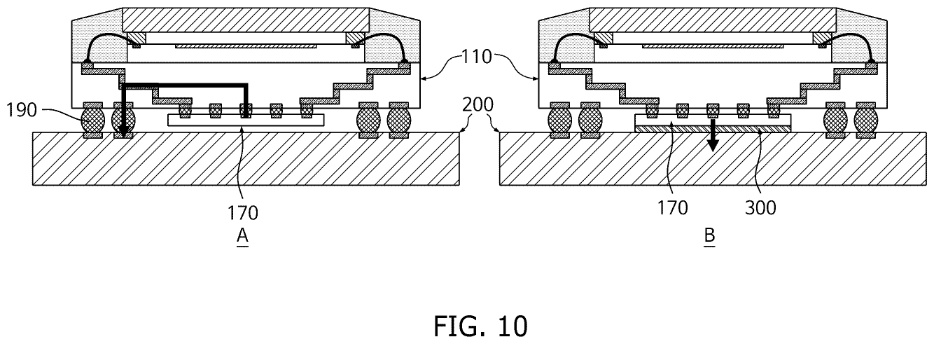

FIG. 10 is a diagram illustrating an example of a heat dissipation path in the semiconductor device. A semiconductor device (shown as device “A”) without the heat transfer member 300 may have a gap present between the second semiconductor chip 170 and a system substrate 200, making it difficult for the heat generated from the second semiconductor chip 170 to be directly transferred to the system substrate 200 beneath the second semiconductor chip 170. As a result, the heat generated from the second semiconductor chip 170 may be transferred to the system substrate 200 through the package substrate 110 and the connection member 190. In this case, the first semiconductor chip 120 disposed on the package substrate 110 may be affected by the heat transferred through the package substrate 110. In particular, if the first semiconductor chip 120 is the image sensor chip, the image may be distorted due to the influence of the heat.

In addition, because the semiconductor device “A” without the heat transfer member 300 has the gap present between the second semiconductor chip 170 and the system substrate 200, a warpage phenomenon may occur, in which the semiconductor device (e.g., the package substrate 110, the first semiconductor chip 120, and/or the second semiconductor chip 170) is bent or deformed (downward) toward the empty space.

As illustrated in FIG. 10, in the semiconductor device according to some embodiments of the present disclosure (shown as device “B”), the heat transfer member 300 is interposed between the second semiconductor chip 170 and the system substrate 200, and the heat transfer member 300 may transfer the heat generated from the second semiconductor chip 170 to the system substrate 200 (e.g. from a surface of the second semiconductor chip 170 to an adjacent surface of the system substrate 200). As a result, the heat generated in the semiconductor device may be smoothly discharged, and the amount of heat transferred to the first semiconductor chip 120 disposed on the package substrate 110 and/or the package substrate 110 may be reduced. Thus, the heat dissipation characteristics of the semiconductor device may be improved, and the performance and reliability of the semiconductor device may be enhanced.

Furthermore, in the semiconductor device according to some embodiments of the present disclosure, the heat transfer member 300 may support the second semiconductor chip 170 between the second semiconductor chip 170 and the system substrate 200 (i.e., from below the second semiconductor chip 170). As a result, the mechanical strength of the semiconductor device may be reinforced, and the warpage phenomenon in which the semiconductor device bends or deforms can be prevented. As a result, the performance and reliability of the semiconductor device can be enhanced.

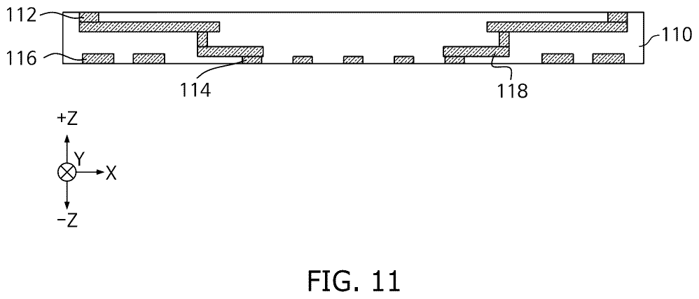

FIGS. 11 to 16 are schematic cross-sectional views illustrating an example of a method for manufacturing a semiconductor device 10.

Referring to FIG. 11, the package substrate 110 may be prepared. The package substrate 110 may have a first surface and a second surface opposite to the first surface. The package substrate 110 may include the bonding pads 112 formed on the first surface, the first contact pad 114 and the second contact pad 116 formed on the second surface, and the wiring layer 118 formed between the first surface and the second surface.

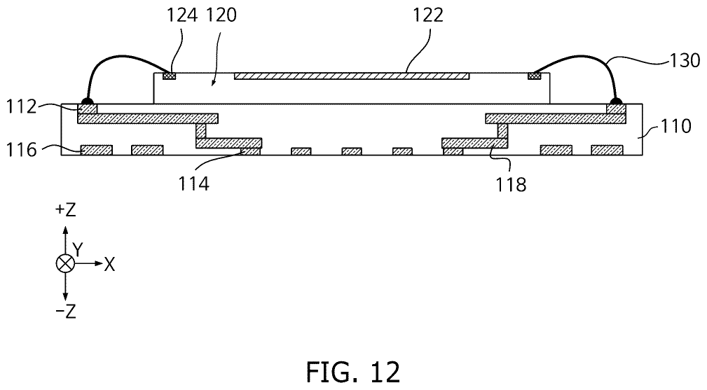

Referring to FIG. 12, the first semiconductor chip 120 may be disposed on the package substrate 110. The first semiconductor chip 120 may include the first chip pad 124 formed on one surface (e.g., the upper surface) of the first semiconductor chip 120. The first semiconductor chip 120 may be disposed on the first surface of the package substrate 110 such that one surface thereof having the first chip pad 124 formed thereon faces upward.

The first semiconductor chip 120 may be an image sensor chip that includes the sensor unit 122. The first semiconductor chip 120 may be disposed on the package substrate 110 such that the sensor unit 122 faces upward. The sensor unit 122 may include a pixel area including a plurality of pixels, and the pixels may be disposed in a 2D array structure within the pixel area. In this case, the first chip pad 124 may be disposed in a peripheral area surrounding the sensor unit 122 (pixel area) of the first semiconductor chip 120.

The first semiconductor chip 120 may be electrically connected to the package substrate 110 through a wire bonding process of connecting the first chip pad 124 and the bonding pad 112 using the bonding wire 130. The wire bonding process may be performed using a capillary, for example. Through the wire bonding process, one end of the bonding wire 130 may be connected to the first chip pad 124, and the other end of the bonding wire 130 may be connected to the bonding pad 112.

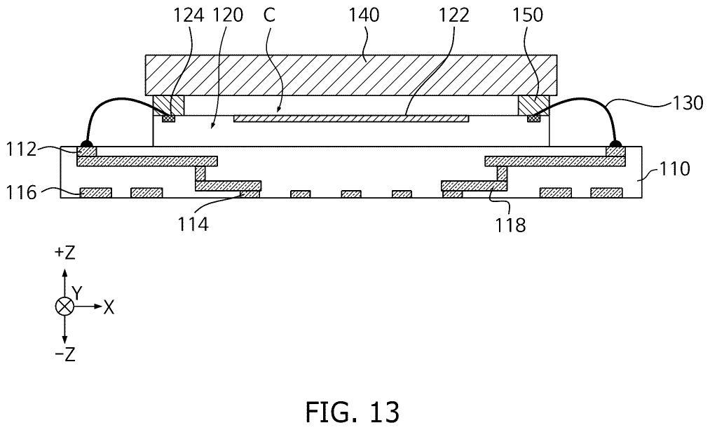

Referring to FIG. 13, the dam 150 may be formed on the upper surface of the first semiconductor chip 120. The dam 150 may be formed in a dispensing manner using a dispenser. For example, the dam 150 may be formed to have shape of a rectangular ring surrounding the outer portion of the upper surface of the first semiconductor chip 120.

The transparent cover member 140 may be stacked on the dam 150. For example, stacking the transparent cover member 140 may be performed while applying heat and pressure. The dam 150 may be attached to the transparent cover member 140 through viscosity and/or adhesion, and may seal the cavity C.

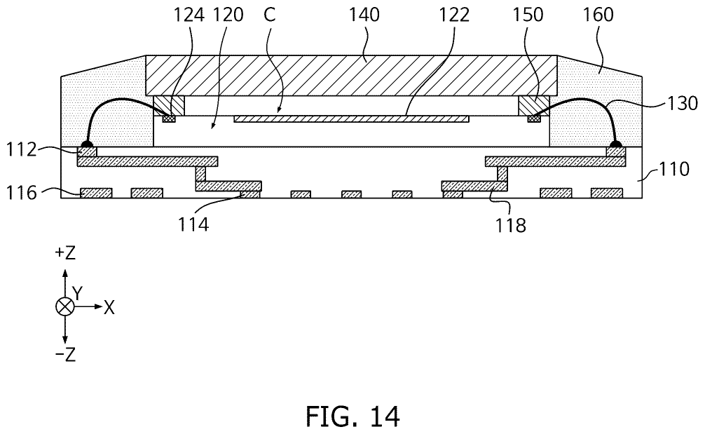

Referring to FIG. 14, the molding member 160 may be applied to the first surface of the package substrate 110, encapsulating the outer surfaces of the first semiconductor chip 120, the dam 150, and the transparent cover. The molding member 160 may cover the outer surfaces of the first semiconductor chip 120 and the dam 150. In addition, the molding member 160 may cover the sides and a portion of a bottom surface of the transparent cover member 140. In addition, the molding member 160 may cover at least a portion of the first surface of the package substrate 110 and at least a portion of the bonding wire 130.

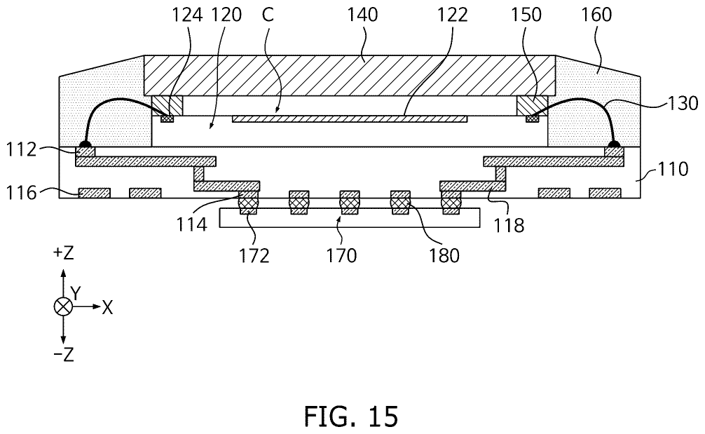

Referring to FIG. 15, the second semiconductor chip 170 may be mounted on the second surface of the package substrate 110. The second semiconductor chip 170 may include an image signal processor and/or a power management integrated circuit. The second semiconductor chip 170 may include the second chip pad 172 formed on one surface. The bump 180 (e.g., a solder bump, etc.) may be formed on the second chip pad 172 of the second semiconductor chip 170. The second semiconductor chip 170 may be disposed such that the surface thereof having the second chip pad 172 formed thereon faces the second surface of the package substrate 110. The bump 180 formed on the second chip pad 172 may be in contact with the first contact pad 114 of the package substrate 110. In a state in which the bump 180 of the second semiconductor chip 170 is in contact with the first contact pad 114, a reflow process or a thermal compression (TC) process, etc. may be performed. The bump 180 may be fused by high temperature and bonded to the second chip pad 172 and the first contact pad 114. The second semiconductor chip 170 and the package substrate 110 may be electrically connected to each other through the bump 180.

An underfill layer covering the bump 180 may be further formed. For example, the underfill layer covering the bump 180 may be formed by a capillary underfill (CUF) process but is not limited thereto.

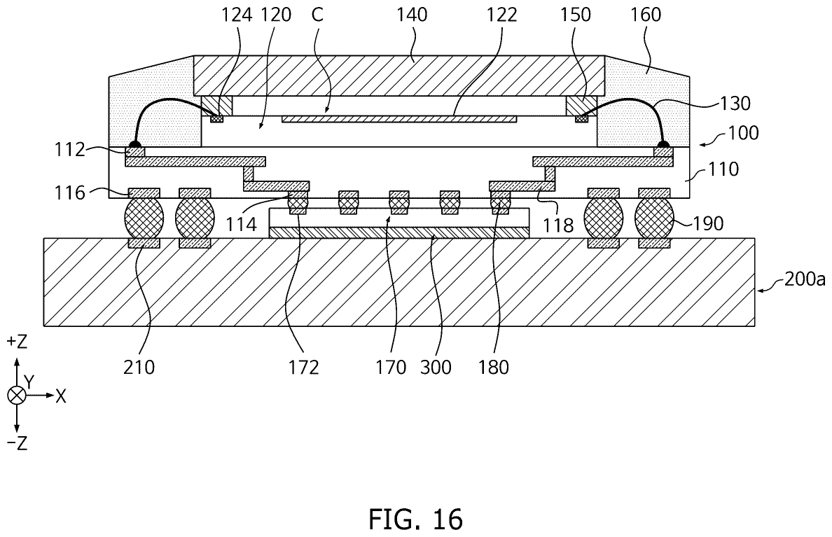

Referring to FIG. 16, the system substrate 200a may be prepared. The system substrate 200a may include the substrate pad 210 formed on one surface. The semiconductor package 100 may be mounted on the system substrate 200a. Specifically, the connection member 190 electrically connecting the package substrate 110 and the system substrate 200a, and the heat transfer member 300 interposed between the second semiconductor chip 170 and the system substrate 200a may be formed.

For example, the connection member 190 may be formed on the second contact pad 116 of the package substrate 110, and the heat transfer member 300 may be formed on a surface opposite to the surface of the second semiconductor chip 170 where the second chip pad 172 is formed. Then, in a state in which the connection member 190 is in contact with the substrate pad 210 on the system substrate 200a and the heat transfer member 300 is in contact on the area surrounded by the substrate pad 210 of the system substrate 200a, a reflow process or a thermal compression process, etc. may be performed.

In another example, the connection member 190 may be formed on the substrate pad 210 of the system substrate 200a, and the heat transfer member 300 may be formed on the area surrounded by the substrate pad 210 of the system substrate 200a. Then, in a state in which the connection member 190 is in contact with the second contact pad 116 of the package substrate 110 and the heat transfer member 300 is in contact on the surface opposite to the surface of the second semiconductor chip 170 where the second chip pad 172 is formed, a reflow process or a thermal compression process, etc. may be performed.

In yet another example, a first sub-connection member may be formed on the second contact pad 116 of the package substrate 110, and a second sub-connection member may be formed on the substrate pad 210 of the system substrate 200a. In addition, the heat transfer member 300 may be formed on a surface opposite to the surface of the second semiconductor chip 170 where the second chip pad 172 is formed and/or on the area surrounded by the substrate pad 210 of the system substrate 200a. In a state in which the first sub-connection member and the second sub-connection member are in contact each other and the heat transfer member 300 is in contact with the second semiconductor chip 170 and the system substrate 200a, a reflow process or a thermal compression process, etc. may be performed. As such, the first sub-connection member and the second sub-connection member may form the connection member 190.

Thus, the connection member 190 electrically connecting the package substrate 110 and the system substrate 200a, and the heat transfer member 300 interposed between the second semiconductor chip 170 and the system substrate 200a may be formed. The connection member 190 and the heat transfer member 300 may be formed of the same material but is not limited thereto.

As a result, the semiconductor device 10 including the heat transfer member 300 may be manufactured.

The description of the method of manufacturing described above with reference to FIG. 11 to 16 is merely an example, and it may be implemented differently in some embodiments.

For example, in some embodiments, the order of respective operations may be changed, some of the operations may be repeatedly performed, some may be omitted, or some may be added.

Although the present disclosure has been described above by way of certain embodiments and drawings, the present disclosure is not limited thereto, and various changes and modifications can be made within the equivalent scope of the technical idea of the present disclosure and the claims to be described below by those of ordinary skill in the art.

What is claimed is:

1. A semiconductor package, comprising:
a package substrate on a system substrate, wherein the package substrate comprises a first surface and a second surface opposite the first surface, the second surface facing the system substrate;
a connection member electrically connecting the system substrate and the package substrate;
a first semiconductor chip on the first surface of the package substrate;
a second semiconductor chip on the second surface of the package substrate, and electrically connected to the first semiconductor chip; and
a heat transfer member between the second semiconductor chip and the system substrate.

2. The semiconductor package according to claim 1, wherein
a first portion of the heat transfer member is in contact with the second semiconductor chip, and
a second portion of the heat transfer member is in contact with the system substrate.

3. The semiconductor package according to claim 1, wherein the first semiconductor chip is an image sensor chip.

4. The semiconductor package according to claim 3, wherein the second semiconductor chip comprises an image signal processor that is configured to convert an electrical signal generated by the image sensor chip into a digital signal.

5. The semiconductor package according to claim 3, wherein the second semiconductor chip comprises a power management integrated circuit configured to control power provided to the image sensor chip.

6. The semiconductor package according to claim 1, wherein
the first semiconductor chip is on the first surface of the package substrate such that an inactive surface thereof faces the first surface of the package substrate, and the second semiconductor chip is on the second surface of the package substrate such that an active surface thereof faces the second surface of the package substrate.

7. The semiconductor package according to claim 1, wherein
the package substrate comprises a bonding pad on the first surface of the package substrate,
the first semiconductor chip comprises a first chip pad, and
the semiconductor package further comprises a bonding wire electrically connecting the bonding pad of the package substrate and the first chip pad of the first semiconductor chip.

8. The semiconductor package according to claim 1, wherein
the package substrate comprises a contact pad on the second surface of the package substrate,
the second semiconductor chip comprises a second chip pad, and
the semiconductor package further comprises a conductive bump electrically connecting the contact pad of the package substrate and the second chip pad of the second semiconductor chip.

9. The semiconductor package according to claim 1, wherein the heat transfer member comprises a same material as the connection member.

10. A semiconductor device, comprising:
a system substrate; and
a semiconductor package on the system substrate, wherein
the semiconductor package comprises:
a package substrate comprising a first surface and a second surface opposite the first surface, the second surface facing the system substrate;
a connection member electrically connecting the system substrate and the package substrate;
a first semiconductor chip on the first surface of the package substrate;
a second semiconductor chip on the second surface of the package substrate and electrically connected to the first semiconductor chip; and
a heat transfer member between the second semiconductor chip and the system substrate.

11. The semiconductor device according to claim 10, wherein the system substrate comprises a heat-receiving pad on a surface of the system substrate, and the heat transfer member is between the heat-receiving pad and the second semiconductor chip.

12. The semiconductor device according to claim 11, wherein
the system substrate further comprises a plurality of substrate pads on the surface of the system substrate and at least one of the plurality of substrate pads is electrically connected to the connection member, and
wherein the heat-receiving pad is surrounded by the plurality of substrate pads.

13. The semiconductor device according to claim 11, wherein a horizontal cross-sectional area of the heat-receiving pad is substantially equal to a horizontal cross-sectional area of the second semiconductor chip.

14. The semiconductor device according to claim 11, wherein a horizontal cross-sectional area of the heat-receiving pad is greater than a horizontal cross-sectional area of the second semiconductor chip.

15. The semiconductor device according to claim 11, wherein
a first portion of the heat transfer member is in contact with the second semiconductor chip, and
wherein a second portion of the heat transfer member is in contact with the heat-receiving pad.

16. The semiconductor device according to claim 10, further comprising:
first and second wiring patterns on the system substrate and the package substrate respectively,
wherein a number of layers of the first wiring pattern on the system substrate is greater than a number of layers of the second wiring pattern on the package substrate.

17. The semiconductor device according to claim 10, wherein the semiconductor package further comprises:
a dam on the first semiconductor chip in a ring shape at least partially enclosing a cavity; and
a transparent cover member on the dam and at least partially covering an upper portion of the first semiconductor chip.

18. The semiconductor device according to claim 17, wherein the semiconductor package further comprises a molding member on outer surfaces of the first semiconductor chip, the dam, and the transparent cover member.

19. The semiconductor device according to claim 10, wherein the second semiconductor chip is electrically connected to the first semiconductor chip through the package substrate.

20. A semiconductor device, comprising:
a system substrate; and
an image sensor package on the system substrate, wherein
the image sensor package comprises:
a package substrate comprising a first surface, a second surface opposite the first surface and facing the system substrate, and a wiring pattern formed between the first surface and the second surface;
a connection member electrically connecting the system substrate and the package substrate;
an image sensor chip on the first surface of the package substrate, comprising a pixel area at a central region of the image sensor chip, and a peripheral area surrounding the pixel area;
a dam in a ring shape surrounding the pixel area on the peripheral area of the image sensor chip;
a transparent cover member on the dam and on an upper portion of the image sensor chip;
a molding member on outer surfaces of the image sensor chip, the dam, and the transparent cover;
an image signal processor chip on the second surface of the package substrate and electrically connected to the image sensor chip through the wiring pattern of the package substrate; and
a heat transfer member between the image signal processor chip and the system substrate, wherein a first portion of the heat transfer member is in contact with the image signal processor chip and a second portion is in contact with the system substrate.
